(19) United States
(12) Patent Application Publication
(10) Pub. No.: US 2014/0006904 A1
(43) Pub. Date: Jan. 2, 2014

(54) ENCODING INFORMATION IN ERROR CORRECTING CODES

(71) Applicant: Alexander GENDLER, Kiriat Motzkin (IL)

(72) Inventor: Alexander GENDLER, Kiriat Motzkin (IL)

(73) Assignee: INTEL CORPORATION, Santa Clara, CA (US)

(21) Appl. No.: 13/537,703

(22) Filed: Jun. 29, 2012

(51) Int. Cl. H03M 13/05; G06F 11/10

(52) U.S. Cl. 714/773; 714/E11.035

(57) ABSTRACT

One or more bit values of bits in an error correcting code (ECC) may be modified to convert the ECC to a sequence of bit values that does not correspond to a valid ECC. The conversion of the ECC to this non-ECC bit value sequence may be used to encode additional information about the data associated with the ECC. For example, one or more particular non-ECC bit value sequences may indicate that the data associated with the ECC is poisoned. Other non-ECC bit value sequences may convey other quality of service information or other information, such as a specific thread used to process the data. Systems, methods, computer readable media, and apparatuses are provided.

### BACKGROUND

Hamming and other error correcting codes have been used identify and/or correct data errors. The Hamming codes used in computer memory systems are typically capable of single error correction and double error detection. While these codes are capable of detecting two bit errors, they can only correct one bit errors. Thus, a detected two bit error is an uncorrectable error. A data line containing an uncorrectable error is considered poisoned. To minimize resource use on poisoned data lines, it is preferable to identify poisoned data line as early as possible. Two existing approaches have been used in the past.

In a first approach, an additional bit has been added to each error correcting code. The additional bit has been used to indicate whether the data associated with the error correcting code is poisoned or not. This approach provide for early identification of poisoned data but is inefficient in that it requires use of additional limited cache memory that could otherwise be used to store additional data.

In a second approach, an uncorrectable error has been forced at the beginning of a poisoned data line by inverting data bits at the beginning of the data line to provide an early identification of a poisoned data line. This approach however makes it difficult to identify the source and/or cause of the uncorrectable error for diagnostic purposes.

There is a need for an early identification of poisoned data lines that does not require the use of additional memory while also allowing for an identification of a source of an uncorrectable error in the poisoned data line.

### BRIEF DESCRIPTION OF THE DRAWINGS

FIG. 1 shows a block diagram of a computer system in an embodiment of the invention.

FIG. 2 shows an exemplary process in an embodiment of the invention.

FIG. 3 shows an exemplary sequence of events in an embodiment of the invention.

FIG. 4 shows an exemplary apparatus in an embodiment of the invention.

FIG. 5 shows an exemplary architecture of a system in an embodiment of the invention.

### DETAILED DESCRIPTION

In an embodiment of the invention, one or more bit values of bits in an error correcting code (ECC) may be modified to convert the ECC to a sequence of bit values that does not correspond to a valid ECC. The conversion of the ECC to this non-ECC bit value sequence may be used to indicate that the data associated with the ECC is poisoned. This approach may have no need for additional memory beyond that already used by the ECC. Additionally, because the poison data indication is stored in the ECC separate from the data containing the uncorrectable error, the source of the uncorrectable error and other information about the uncorrectable error may still be collected and analyzed.

This ECC bit value modification may be possible in error correcting coding schemes in which only a subset of theoretical combinations of bit values in an error correcting code are actually used. One example of this is in Hamming codes used in computer memory systems that provide single error correction and double error detection (SECDEC).

In these Hamming codes, every column in a matrix generated from linear code data has an odd number of at least three set bits. Each different combination of set bits may be used to represent a different data bit. Generally, the least number of set bits are used to represent the data. Thus, if the linear code data may be represented by each of the different combinations of three set bits, then only three set bits may be used in the generated matrix. If not, then a determination may be made whether the linear code data may be represented by different combinations of three set bits together with combinations of five set bits. If the three and five set bit combinations are sufficient to represent the linear code data, then only the three and five set bit combinations may be used in the generated matrix. If not, then a determination may be made whether the linear code data may be represented by different combinations of three, five, and seven set bits, and so on.

The number of data bits that may be protected by these Hamming codes are 2̂(n−2), where n is the number of ECC bits. In those situations where the number n of ECC bits is 7 or more and the number of data bits is 32 or more, only a subset of all possible set bit combinations are actually used for error correction and/or detection. For example, when number n of ECC bits is 7, then the number of possible combinations of three set bits out of the 7 parity bits is 7!/((7−3)!(3!))=(7*6*5)/(3*2*1)=35. Since 7 ECC bits can protect up to 32 data bits, the 35 three set bit combinations is sufficient to cover the 32 data bits. Additionally, because the three set bit combinations are sufficient to cover the 32 data bits, there is no need to use combinations of five or seven set bits. Thus, in this example, only some of the three set bit combinations are actually used, and none of the five and seven set bit combinations are actually used.

In general, if there are 7 or more ECC bits and 32 or more data bits, where the number of data bits is equal to 2̂(n−2), with n representing the number of ECC bits, then the complete set of data bits may be fully covered by the different combinations of three and five set bits. Higher order set bit combinations, such as combinations of seven set bits, nine set bits, eleven set bits, and so on, need not be used to cover the set of data bits.

An error indication algorithm may then be configured to ignore these higher bit value combinations, instead focusing on the three and five set bits combinations that are associated with the data bits. Because the seven and higher set bit combinations are never used and may be configured to be ignored by the error indication algorithm, these bit combinations may be used instead for other purposes, including for encoding additional information. An ECC transformation circuit, bit inverting arrangement, and/or XOR gates may be used to invert one or more bits in an ECC to create a combination of seven or more set bits.

In some instances, different combinations of these unused set bit combinations may by associated with different events or information. For example, a first combination of seven set bits may designate the data associated with the first combination as poisoned. Other combinations of seven or more set bits may identify specific threads used to read the data bits. Other combinations of seven or more set bits may be use to specify a quality of service or priority of the data associated with the respective combination. Other events or information may be associated with unused set bit combinations in different embodiments.

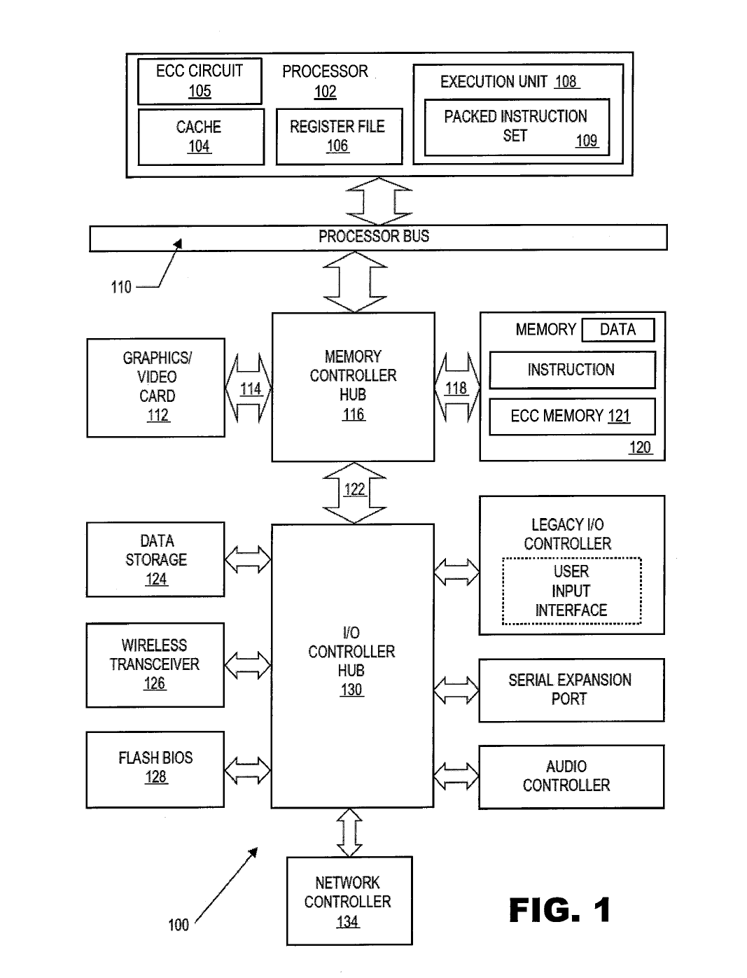

FIG. 1 shows a block diagram of an exemplary computer system formed with a processor that includes execution units to execute an instruction in accordance with one embodiment of the present invention. System 100 includes a component, such as a processor 102 to employ execution units including logic to perform algorithms for process data, in accordance with the present invention, such as in the embodiment described herein. System 100 is representative of processing systems based on the PENTIUM® III, PENTIUM® 4, Xeon™, Itanium®, XScale™ and/or StrongARM™ microprocessors available from Intel Corporation of Santa Clara, Calif., although other systems (including PCs having other microprocessors, engineering workstations, set-top boxes and the like) may also be used. In one embodiment, sample system 100 may execute a version of the WINDOWS™ operating system available from Microsoft Corporation of Redmond, Wash., although other operating systems (UNIX and Linux for example), embedded software, and/or graphical user interfaces, may also be used. Thus, embodiments of the present invention are not limited to any specific combination of hardware circuitry and software.

Embodiments are not limited to computer systems. Alternative embodiments of the present invention can be used in other devices such as handheld devices and embedded applications. Some examples of handheld devices include cellular phones, Internet Protocol devices, digital cameras, personal digital assistants (PDAs), and handheld PCs. Embedded applications can include a micro controller, a digital signal processor (DSP), system on a chip, network computers (NetPC), set-top boxes, network hubs, wide area network (WAN) switches, or any other system that can perform one or more instructions in accordance with at least one embodiment.

FIG. 1 shows a block diagram of a computer system 100 formed with a processor 102 that includes one or more execution units 108 to perform an algorithm to perform at least one instruction in accordance with one embodiment of the present invention. One embodiment may be described in the context of a single processor desktop or server system, but alternative embodiments can be included in a multiprocessor system. System 100 is an example of a ‘hub’ system architecture. The computer system 100 includes a processor 102 to process data signals. The processor 102 can be a complex instruction set computer (CISC) microprocessor, a reduced instruction set computing (RISC) microprocessor, a very long instruction word (VLIW) microprocessor, a processor implementing a combination of instruction sets, or any other processor device, such as a digital signal processor, for example. The processor 102 is coupled to a processor bus 110 that can transmit data signals between the processor 102 and other components in the system 100. The elements of system 100 perform their conventional functions that are well known to those familiar with the art.

In one embodiment, the processor 102 includes a Level 1 (L1) internal cache memory 104. Depending on the architecture, the processor 102 can have a single internal cache or multiple levels of internal cache. Alternatively, in another embodiment, the cache memory can reside external to the processor 102. Other embodiments can also include a combination of both internal and external caches depending on the particular implementation and needs. Register file 106 can store different types of data in various registers including integer registers, floating point registers, status registers, and instruction pointer register.

In an embodiment, the processor 102 may include an error correcting code (EEC) transformation circuit 105 that may be configured to selectively invert at least one bit in an EEC in response to the EEC memory 121 detecting an uncorrectable error in data read from cache memory 104 based on the ECC. The uncorrectable error may be a detected double-error in a word read from the cache 104. The double-error may be detected by analyzing the data read from the cache, generating a matrix from the analysis, and comparing the generated matrix to the ECC.

Execution unit 108, including logic to perform integer and floating point operations, also resides in the processor 102. The processor 102 also includes a microcode (ucode) ROM that stores microcode for certain macroinstructions. For one embodiment, execution unit 108 includes logic to handle a packed instruction set 109. By including the packed instruction set 109 in the instruction set of a general-purpose processor 102, along with associated circuitry to execute the instructions, the operations used by many multimedia applications may be performed using packed data in a general-purpose processor 102. Thus, many multimedia applications can be accelerated and executed more efficiently by using the full width of a processor's data bus for performing operations on packed data. This can eliminate the need to transfer smaller units of data across the processor's data bus to perform one or more operations one data element at a time.

Alternate embodiments of an execution unit 108 can also be used in micro controllers, embedded processors, graphics devices, DSPs, and other types of logic circuits. System 100 includes a memory 120. Memory 120 can be a dynamic random access memory (DRAM) device, a static random access memory (SRAM) device, flash memory device, or other memory device. Memory 120 can store instructions and/or data represented by data signals that can be executed by the processor 102.

Memory 120 may also include ECC memory 121. ECC memory 121 may include a type of computer data storage arrangement configured to detect at least one of type of uncorrectable error. The computer data storage arrangement may also be configured in some instances to correct a single error and detect a double error in a particular word or sequence of bits.

A system logic chip 116 is coupled to the processor bus 110 and memory 120. The system logic chip 116 in the illustrated embodiment is a memory controller hub (MCH). The processor 102 can communicate to the MCH 116 via a processor bus 110. The MCH 116 provides a high bandwidth memory path 118 to memory 120 for instruction and data storage and for storage of graphics commands, data and textures. The MCH 116 is to direct data signals between the processor 102, memory 120, and other components in the system 100 and to bridge the data signals between processor bus 110, memory 120, and system I/O 122. In some embodiments, the system logic chip 116 can provide a graphics port for coupling to a graphics controller 112. The MCH 116 is coupled to memory 120 through a memory interface 118. The graphics card 112 is coupled to the MCH 116 through an Accelerated Graphics Port (AGP) interconnect 114.

System 100 uses a proprietary hub interface bus 122 to couple the MCH 116 to the I/O controller hub (ICH) 130. The ICH 130 provides direct connections to some I/O devices via a local I/O bus. The local I/O bus is a high-speed I/O bus for connecting peripherals to the memory 120, chipset, and processor 102. Some examples are the audio controller, firmware hub (flash BIOS) 128, wireless transceiver 126, data storage 124, legacy I/O controller containing user input and keyboard interfaces, a serial expansion port such as Universal Serial Bus (USB), and a network controller 134. The data storage device 124 can comprise a hard disk drive, a floppy disk drive, a CD-ROM device, a flash memory device, or other mass storage device.

For another embodiment of a system, an instruction in accordance with one embodiment can be used with a system on a chip. One embodiment of a system on a chip comprises of a processor and a memory. The memory for one such system is a flash memory. The flash memory can be located on the dame die as the processor and other system components. Additionally, other logic blocks such as a memory controller or graphics controller can also be located on a system on a chip

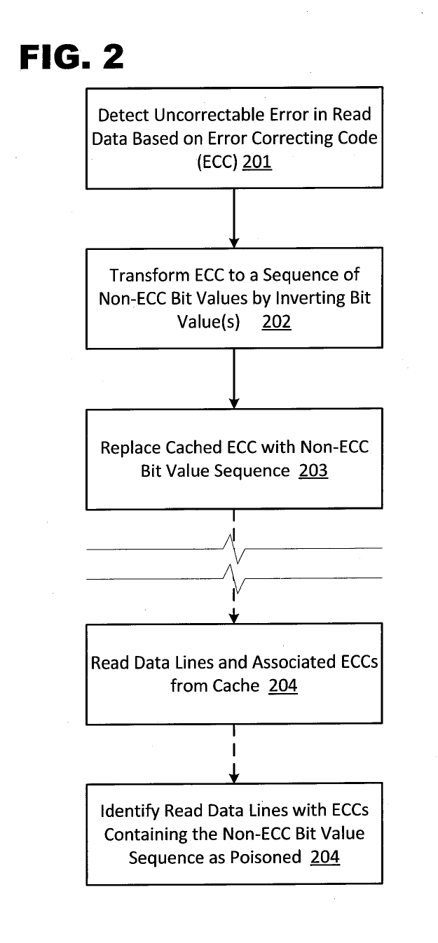

FIG. 2 shows an exemplary process in an embodiment of the invention. In some instances, the process may be stored in instructions stored on a non-transitory computer readable medium that when executed by a processing device, cause the processing device to perform the process. Boxes 201 to 203 may relate to the detection and marking of poisoned data having uncorrectable errors. Boxes 204 and 205 may relate to a subsequent identification of poison data that has been marked in boxes 201 to 203.

In box 201, an uncorrectable error in data read from a cache may be detected based on a cached error-correcting code (ECC) associated with the read data. In a single error correction, double error detection Hamming code, an uncorrectable error may be detected by comparing a matrix generated from a set of data read from a cache to a previously created ECC associated with the read data. If a result of the comparison includes an odd number of ones, then the read data may include a single correctable error. If the result of the comparison includes an even number of ones, then the read data may include a double and uncorrectable error. If the result of the comparison does not include any ones, then the read data may be free of errors.

In box 202, at least one bit in the ECC associated with the read data having the uncorrectable error may be inverted to transform the ECC into a predetermined non-ECC bit value sequence. For example, as discussed above, Hamming codes in computer memory systems providing SECDEC that have at least 7 ECC bits for protecting at least 32 data bits need only use combinations of three and five set bits to fully cover the data bits. As a result, the ECC need not support combinations of 7 or more set bits, and the various combinations of 7 or more set bits may correspond to non-ECC bit value sequences. A bit inverting arrangement that may include one or more XOR gates and/or an ECC transformation circuit may be used to invert one or more bits in an ECC to transform the ECC into a predetermined non-ECC bit value sequence, which may correspond to one of the combinations of 7 or more set bits that are not used to cover the data bits.

In box 203, at least a portion of the ECC may be replaced with the predetermined non-ECC bit value sequence. This replacement may occur by writing the predetermined non-ECC bit value sequence to a cache, computer readable medium, or other memory in lieu of the portion of the ECC that it replaces.

Boxes 204 and 205 may occur at any time after the ECC or portion thereof is replaced with the predetermined non-ECC bit value sequence and may occur independently from boxes 201 to 203. In box 204, one or more data words and/or data lines may be read from a cache or other memory. The ECCs, including those with the predetermined non-ECC bit value sequences, that are associated with the read data words and/or data lines may also be read from the cache or other memory.

In box 205, the read ECCs may be analyzed to identified those having the predetermined non-ECC bit value sequence. As discussed previously, in those situations where SECDED Hamming codes are used to generate the ECCs, the predetermined non-ECC bit value sequence may correspond to a predetermined sequence of bit values that does not relate to the data bits protected by the SECDED Hamming code. For example, in those situations discussed above where only three and five set bit combinations may be associated with different data bits, the predetermined non-ECC bit value sequence may correspond to a combination of seven set bits. The data words and/or data lines associated with the read ECCs having the predetermined non-ECC bit value sequence may then be identified as poisoned.

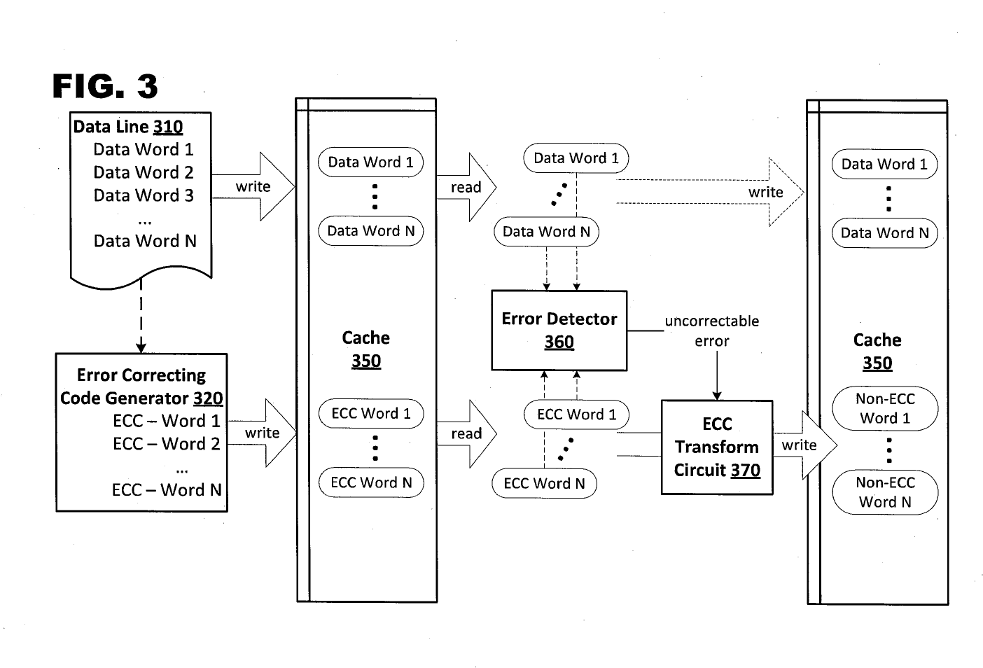

FIG. 3 shows an exemplary sequence of events in an embodiment. Initially, a data line 310 including a set of N data words may be selected for caching. Prior to writing the data line 310 to the cache 350, an error correcting code generator 320 may apply a SECDED Hamming code algorithm to the data in the data line 310. The error correcting code generator 320 may then generate an ECC including a set of N ECC code words which may also be written to the cache 350.

Later, when the data line 310 and/or the set of N data words are read from the cache 350, the read data words, an error detector 360 may generate a matrix from the read data words and compare the matrix to the ECC and/or the code words in the ECC, which may also be read from cache 350. If the error detector 360 detects an uncorrectable error based on the comparison, the error detector 360 may send a signal to the ECC transformation circuit 370. After receiving this signal, the ECC transformation circuit 370 may modify one or more bits in the ECC to generate a sequence of bit values that does not correspond to a recognized ECC bit combination associated with the data bits. The error detector 360 may detect an uncorrectable error in some instances if there is an even number of ones in an output of the comparison of the generated matrix to the ECC.

The modified ECC including the sequence of bit values that does not correspond to a recognized ECC bit combination may then be written to the cache 350 or another memory. Later, the ECCs stored in the cache 350 may be read, and the data words and/or data lines associated with the read ECCs having the predetermined non-ECC bit value sequence may then be identified as poisoned. If the ECCs are analyzed in this manner either before the data words and/or data lines containing the uncorrectable/poisoned data are read or early in the reading process, the reading process may be aborted earlier or another action may be taken to improve performance and efficiency.

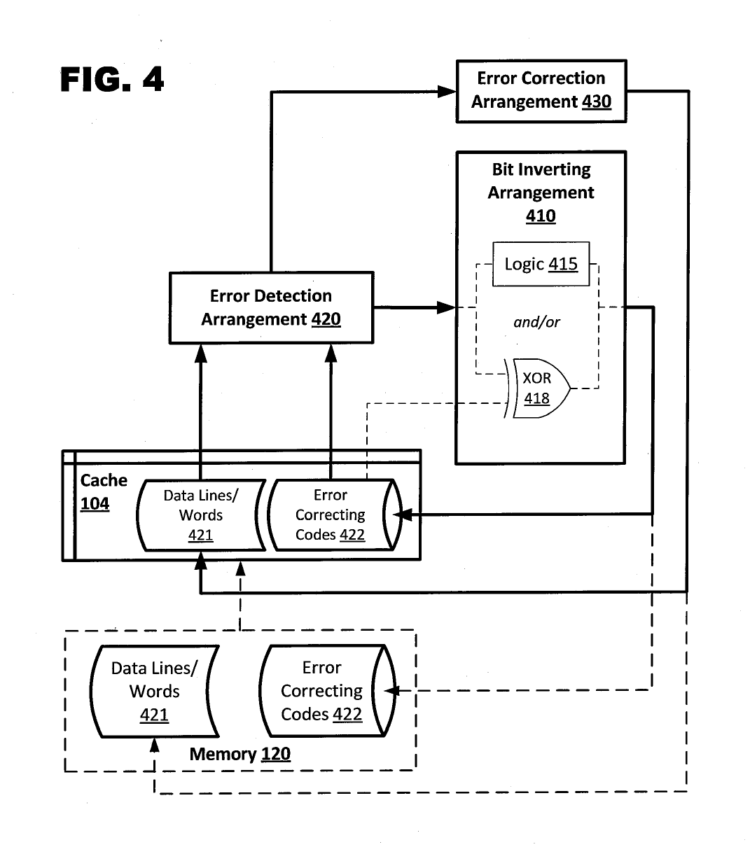

FIG. 4 shows an exemplary apparatus in an embodiment of the invention. In some instances, data lines and/or words 421 and error correcting codes (ECCs) 422 associated with the data lines 421 may be stored in a memory 120 or other data storage device and read from the memory 120 into a cache 104. The cache 104 may store one or more data line 421 and an ECC 422 associated with each of the data lines 421. The ECCs 422 may be Hamming codes that are single error correcting and double error detecting (SECDED). These type of Hamming codes may, for a quantity of m error correcting code (ECC) symbols or bits, provide protection for ((2̂m)−m−2) data symbols or bits.

An error detecting arrangement 420 may be configured to detect an uncorrectable error in one or more of the data lines 421 read from the cache 104 based on the ECC 422 associated with the respective data line 421. In some instances, this detection may be made by generating a matrix from a read data line 421 and comparing the matrix to the ECC 422 associated with the respective data line 421. If the result of the comparison includes an even number of ones, the data line 421 read from the cache 104 may include an uncorrectable error. In this respect, the error detecting arrangement 420 may detect an uncorrectable error when detecting a double error in the data line read from the cache based on ECC 422 and the result of the comparison of the ECC to the read data line. Other error detecting techniques may be used in other embodiments.

In some instances, an error correction arrangement 430 may be configured to correct a single error in data read from the cache 104 based on the ECC 422. The error correcting arrangement 430 coupled to or integrated as part of the error detection arrangement 420. In some instances the error correction arrangement 430 may be triggered in response to the error detection arrangement 420 detecting a single error in data read from the cache 104. The error correction arrangement 430 may, in some instances, be configured to correct the data stored in the cache 104, memory 120, or other data storage device.

If the error detecting arrangement 420 detects an uncorrectable error the data line 421 read from the cache 104, the error detecting arrangement may send a signal to a coupled bit inverting arrangement 410. The bit inverting arrangement 410 may include inverters, logic 415 and/or one or more XOR gates 418. The bit inverting arrangement 410 may be configured to transform at least a portion of the ECC 422 associated with the read data line 421 having the uncorrectable error into a predetermined non-ECC bit value sequence. The predetermined non-ECC bit value sequence may include a sequence of bits that are not associated with a known ECC. For example, in those situations discussed above where only three and five set bit combinations may be associated with different data bits, the known ECCs may include those three and five set bit combinations associated with the data bits. Since the combinations of seven or more set bits are not, in this example, associated with any data bits, the combinations of seven or more set bits are not, in this example, associated with a known ECC and may be used as the predetermined ECC bit value sequence in an embodiment.

In some instances where the bit inverting arrangement 410 includes multiple XOR gates 418, each of the XOR gates 418 may be associated with a different bit position of an ECC 422. An input of each of the XOR gates 418 may be coupled to an output of the error detecting arrangement 420.

In some instances where the bit inverting arrangement 410 includes logic 415, logic 415 may be configured to select one or more predetermined non-ECC bit value sequences from a set of two or more non-ECC bit value sequences. Each of the non-ECC bit value sequences in the set may be associated with and/or conveying different information about the data line and/or words associated with an ECC modified to the respective non-ECC bit value sequence.

In some instances, one or more non-ECC bit value sequences may be reserved for and/or associated with data designated as poisoned for including an uncorrectable error. Logic 415 may be configured to select one of these reserved non-ECC bit value sequences when the error detecting arrangement 420 detects an uncorrectable error in the data line read from the cache.

Logic 415 may be configured to select a non-ECC bit value sequence from a set of non-ECC bit value sequences that are associated with and/or convey different quality of service information, including but not limited to priority information. In some instances, these set of non-ECC bit value sequences may be a subset of the sequences reserved for poisoned data, so that the selected non-ECC bit value sequence may provide additional quality of service information in addition to identifying poisoned data. Logic 415 may be configured to select the non-ECC bit value sequence from the set that corresponds to a measured or desired quality of service for the data associated with the non-ECC bit value sequence.

In some instances, logic 415 may be configured to select a non-ECC bit value sequence identifying a particular thread used during the reading of the cached data line. In some instances, these set of non-ECC bit value sequences may be a subset of the sequences reserved for poisoned data, so that the selected non-ECC bit value sequence may provide additional thread information in addition to identifying poisoned data. This selected non-ECC bit value sequence may later be used to identify the thread used for diagnostic or other purposes.

The bit inverting arrangement 410 may then output the transformed ECC or portion thereof, which may be stored in the cache 104, memory 120, or other data storage device. The transformed ECC or portion thereof may modify, overwrite, and/or replace the original ECC 422 stored in the respective cache 104, memory 120, and/or other data storage device.

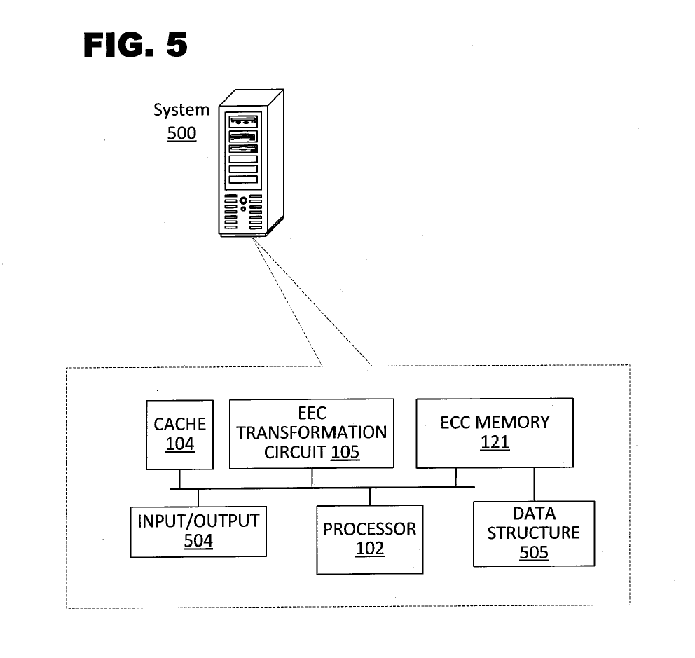

FIG. 5 shows an exemplary architecture of a system 500. System 500 may include a processor 102, cache 104, ECC transformation circuit 105, ECC memory 121, and communications interface 504, all of which may be communicatively coupled through a system bus and/or other busses. In various embodiments, system 300 may have an architecture with modular hardware and/or software systems that include additional and/or different systems communicating through one or more networks.

Communications device 504 may enable connectivity between the processing devices 102 in system 300 and that of other systems (not shown) by encoding data to be sent from the processing device 102 to another system and decoding data received from another system for the processing device 102.

In an embodiment, ECC memory 121 may contain different components for retrieving, presenting, changing, and saving data and may include a computer readable medium. ECC memory 121 may include a type of computer data storage arrangement configured to detect at least one of type of uncorrectable error in a data line that may be read from a cache 104 storing the data line. The computer data storage arrangement may also be configured in some instances to correct a single error and detect a double error in a particular word or sequence of bits. The computer data storage arrangement may include a variety of memory devices, for example, Dynamic Random Access Memory (DRAM), Static RAM (SRAM), flash memory, cache memory, and other memory devices.

Additionally, for example, ECC memory 121 and processing device(s) 102 may be distributed across several different computers that collectively comprise a system. ECC memory 121 and/or cache 104 may include one or more data structures 505. The data structures 505 may be capable of different types of structured data, such as data lines or matrices. ECC memory 121 may also be configured to correct a correctable single error based on the ECC and designate a detected double error as an uncorrectable error.

The EEC transformation circuit 105 may be configured to selectively invert at least one bit in an EEC in response to the EEC memory 121 detecting an uncorrectable error in data read from cache memory 104 based on the ECC associated with the read data. The uncorrectable error may be a detected double-error in a word read from the cache 104. The double-error may be detected by analyzing the data read from the cache, generating a matrix from the analysis, and comparing the generated matrix to the ECC. In some instances, an uncorrectable error in the data may be identified if the result of the comparison includes an even number of ones.

Processing device 102 may perform computation and control functions of a system and comprises a suitable central processing unit (CPU). Processing device 102 may include a single integrated circuit, such as a microprocessing device, or may include any suitable number of integrated circuit devices and/or circuit boards working in cooperation to accomplish the functions of a processing device. Processing device 102 may execute computer programs, such as object-oriented computer programs, within a memory such as ECC memory 121.

Processing device 102 may be configured to generate a single-error correcting and double-error detecting error correcting code (ECC) for data in a data line. The bit values of the ECC generated by the processing device 102 may be limited to a subset of all possible bit value combinations for a bit length of the ECC. The ECC transformation circuit 105 may invert at least one bit in the ECC to generate new bit values that are not within the limited subset generated by the processing device 102. In this respect, the ECC transformation circuit 105 may be configured to transform the ECC into a predetermined non-ECC bit value sequence that is not within the limited subset of ECC bit values generated by the processing device 102.

The foregoing description has been presented for purposes of illustration and description. It is not exhaustive and does not limit embodiments of the invention to the precise forms disclosed. Modifications and variations are possible in light of the above teachings or may be acquired from the practicing embodiments consistent with the invention. For example, the ECC memory 121 and/or cache 104 need not be coupled to the processing device 102 through a system bus but may instead be otherwise directly or indirectly coupled to the processing device 102.

We claim:

1. An apparatus comprising:
a cache for storing a data line and an error-correcting code (ECC) associated with the data line;
an error detection arrangement for detecting an uncorrectable error in the data line read from the cache based on the cached error-correcting code (ECC) associated with the read data line; and
a bit inverting arrangement for transforming at least a portion of the ECC associated with the data line having the uncorrectable error into a predetermined non-ECC bit value sequence.

2. The apparatus of claim 1, wherein the bit inverting arrangement includes a plurality of XOR gates, each associated with a different bit position of the ECC.

3. The apparatus of claim 2, wherein an input of each XOR gate is coupled to an output of the error detecting arrangement.

4. The apparatus of claim 1, wherein the ECC is a Hamming code that is single-error correcting and double-error detecting.

5. The apparatus of claim 4, wherein the error detection arrangement detects the uncorrectable error responsive to detecting a double-error in the data line read from the cache based on the Hamming code.

6. The apparatus of claim 4, further comprising an error correction arrangement for correcting a single-error in the data line read from the cache based on the Hamming code.

7. The apparatus of claim 1, wherein the predetermined non-ECC bit value sequence includes a sequence of bits that are not associated with a known ECC.

8. The apparatus of claim 1, wherein the bit inverting arrangement includes logic for selecting the predetermined non-ECC bit value sequence from a plurality of non-ECC bit value sequences, each non-ECC bit value sequence conveying different data line information.

9. The apparatus of claim 8, wherein a set of non-ECC bit value sequences conveys different quality of service information about the cached data line and the logic is configured to select the non-ECC bit value sequence from the set that corresponds to a measured quality of service.

10. The apparatus of claim 8, wherein the logic is configured to select a non-ECC bit value sequence identifying a particular thread used during the reading of the cached data line.

11. The apparatus of claim 8, wherein the logic is configured to select a non-ECC bit value sequence designating the data line read from the cache as poisoned responsive to the error detecting arrangement detecting the uncorrectable error in the data line read from the cache.

12. A system comprising:
a processor configured to generate a single error correcting and double error detecting error correcting code (ECC) for data in a data line;
a cache storing the data line;
an ECC memory coupled to the cache for detecting a double error in the data line read from the cache based on the ECC; and
an ECC transformation circuit configured to invert at least one bit in the ECC responsive to the ECC memory detecting the double error.

13. The system of claim 12, wherein bit values of the ECC generated by the processor are limited to a subset of all possible bit values for a bit length of the ECC and the ECC transformation circuit inverts at least one bit in the ECC to generate new bit values that are not within the subset.

14. The system of claim 13, wherein the ECC transformation circuit is configured to transform the ECC into a predetermined non-ECC bit value sequence that is not within the limited subset of ECC bit values.

15. The system of claim 12, wherein the ECC memory is configured to correct a correctable single error based on the ECC and designate a detected double error as an uncorrectable error.

16. A method comprising:
detecting an uncorrectable error in data read from a cache based on an error-correcting code (ECC) associated with the read data;
inverting at least one bit in the ECC to transform the ECC into a predetermined non-ECC bit value sequence; and
replacing at least a portion of the ECC with the predetermined non-ECC bit value sequence.

17. The method of claim 16, further comprising:
reading a plurality of data lines and associated ECCs from the cache; and
identifying as poisoned a read data line associated with an ECC containing the predetermined non-ECC bit value sequence.

18. The method of claim 16, wherein the ECC is a single-error correcting and double-error detecting Hamming code

19. A non-transitory computer readable medium comprising stored instructions that, when executed by a processing device, cause the processing device to:
detect an uncorrectable error in data read from a cache based on a cached error-correcting code (ECC) associated with the read data;
invert at least one bit in the ECC to transform the ECC into a predetermined non-ECC bit value sequence; and
replace the cached ECC with the predetermined non-ECC bit value sequence.

20. The non-transitory computer readable medium of claim 19, further comprising additional instructions that, when executed by a processing device, cause the processing device to:
read a plurality of data lines and associated ECCs from the cache; and
identify as poisoned a read data line associated with an ECC containing the predetermined non-ECC bit value sequence.

21. The non-transitory computer readable medium of claim 19, wherein the ECC is a single-error correcting and double-error detecting Hamming code
